(19) United States
(12) Patent Application Publication
(10) Pub. No.: US 2017/0181317 A1
(43) Pub. Date: Jun. 22, 2017

(54) LIQUID-COOLING HEAT SINK

(71) Applicant: MAN ZAI INDUSTRIAL CO., LTD., Tainan City (TW)

(72) Inventors: Cheng-Chien Wan, Tainan City (TW); Cheng-Feng Wan, Tainan City (TW); Hao-Hui Lin, Tainan City (TW); Hsiao-Ching Chen, Tainan City (TW); Wei-Che Hsiao, Tainan City (TW); Tung-Hsin Liu, Tainan City (TW)

(21) Appl. No.: 15/365,912

(22) Filed: Nov. 30, 2016

(30) Foreign Application Priority Data
Dec. 21, 2015 (TW) 104143022

(51) Int. Cl. H05K 7/20; F28F 3/12

(52) U.S. Cl. CPC H05K 7/20254; F28F 3/12; H05K 7/2039; F28F 2270/02

(57) ABSTRACT

A liquid-cooling heat sink has a heat-conductive tube and multiple heat-conductive units arranged adjacent to the heat-conductive tube. The heat-conductive tube has a first tube and a second tube. An isolation member having an isolation channel is located between the first tube and the second tube. The isolation member obstructs the heat exchange between the first tube and the second tube. A first delivery tube and a second delivery tube of each one of the heat-conductive bodies respectively connect to the first tube and the second tube of the heat-conductive tube, thereby integrating the first tube and the second tube and obstructing the heat exchange between the cooling liquids with different temperatures. Each of the heat-conductive units distributes the cooling liquids with different temperatures by the heat-conductive tube, thereby simplifying the pipeline setting and reducing the volume of the liquid-cooling heat sink.

### CROSS-REFERENCE TO RELATED APPLICATION

Pursuant to 35 U.S.C. §119(a), this application claims the benefit of the priority to Taiwan Patent Application No. 104143022, filed Dec. 21, 2015. The content of the prior application is incorporated herein by its entirety.

### BACKGROUND OF INVENTION

1. Field of the Invention

The present invention is related to a heat sink, and particularly to a liquid-cooling heat sink.

2. Description of the Related Art

In order to dissipate the heat generated by an electric device or an electric apparatus during operation, the electric device or the electric apparatus is equipped with a heat sink to prevent shutdown or damages caused by overheating.

The liquid-cooling heat sink is one of the common heat sinks used for the electric device or the electric apparatus. At least one heat-conductive unit of the conventional liquid-cooling heat sink contacts the main heat-generating source of the electric device or the electric apparatus. The at least one heat-conductive unit has a fluid channel Each fluid channel has two sides. One side of the fluid channel externally connects to a cooling liquid inlet pipe communicating with a cooling liquid source. The other side of the fluid channel connects to a cooling liquid outlet pipe communicating with a reflux part of the cooling liquid source. Therefore, the cooling liquid, such as water or refrigerant, supplied from the cooling liquid source enters from the cooling liquid inlet pipe. The cooling liquid flows through the fluid channel of the heat-conductive unit to cool the main heat-generating source of the electric device or the electric apparatus and becomes a hotter cooling liquid. The hotter cooling liquid then departs from the cooling liquid outlet pipe and refluxes to the reflux part of the cooling liquid source. After the heat dissipating process of the device around the cooling liquid source, the hotter cooling liquid is cooled and exported to the fluid channel again. By the circulation of the cooling liquid, the liquid-cooling heat sink is able to continuously dissipate heat from the main heat-generating source of the electric device or the electric apparatus.

However, the number of the heat-conductive unit of the liquid-cooling heat sink will increase with the number of the main heat-generating source of the electric device or the electric apparatus. Every heat-conductive unit needs to connect to an independent cooling liquid inlet pipe and an independent cooling liquid outlet pipe to communicate with the cooling liquid source. Due to the difficulty of integrating the cooling liquid inlet pipes and the cooling liquid outlet pipes of the conventional liquid-cooling heat sink, the pipeline setting is usually complicate and the volume of the liquid-cooling heat sink is large.

### SUMMARY OF THE INVENTION

The objective of the present invention is to provide a liquid-cooling heat sink to solve the problems of complicate pipeline setting and large volume due to the complicate pipeline setting.

In order to achieve the aforementioned objective, the present invention provides the liquid-cooling heat sink comprising:

a heat-conductive tube having
two opposite sides;
a first tube having
   at least one first fluid channel defined longitudinally in the first tube;
   a first wall surrounding the at least one first fluid channel;
a second tube formed on the first tube;
a second tube having
   at least one second fluid channel defined longitudinally in the second tube; and
   a second wall surrounding the at least one second fluid channel; and
an isolation member formed between and connecting to the first tube and the second tube and having
   at least one isolation channel defined between the first tube and the second tube; and
   multiple connecting walls surrounding the at least one isolation channel and connecting the first wall of the first tube and the second wall of the second tube; and

multiple heat-conductive units located on the two opposite sides of the heat-conductive tube, and each heat-conductive unit having
a heat-conductive body having a fluid channel; each fluid channel having an entrance end and an exit end;
a first delivery tube having two ends, one end of the first delivery tube connecting to the entrance end of the fluid channel, and the other end of the first delivery tube connecting to the at least one first fluid channel of the first tube; and
a second delivery tube having two ends, one end of the second delivery tube connecting to the exit end of the fluid channel, and the other end of the second delivery tube connecting to the at least one second fluid channel of the second tube.

By the aforementioned invention of the liquid-cooling heat sink, the cooling liquids with different temperatures flow within the heat-conductive tube, which has the first tube and the second tube adjacently arranged with each other. The isolation member having the isolation channel acts as an air layer between the first tube and the second tube to obstruct the heat exchange. The first delivery tubes of the heat-conductive bodies communicate with the heat-conductive units and the first tube of the heat-conductive tube, and the second delivery tubes of the heat-conductive bodies communicate with the heat-conductive units and the second tube of the heat-conductive tube, which integrates the first tube and the second tube to provide a flowing route for the cooling liquids with different temperatures by the heat-conductive tube. Besides, it also provides separation and bypass of the cooling liquids of different temperatures to prevent them from influence by each other. Each of the heat-conductive units distributes the cooling liquids of different temperatures by the heat-conductive tube to simplify the pipeline setting and to reduce the volume of the liquid-cooling heat sink.

### BRIEF DESCRIPTION OF THE DRAWINGS

FIG. 1 is a perspective view of a liquid-cooling heat sink;

FIG. 2 is a perspective view of a heat-conductive tube of the liquid-cooling heat sink in FIG. 1;

FIG. 3 is a side view of the heat-conductive tube in FIG. 2;

FIG. 4 is a top view of the liquid-cooling heat sink in FIG. 1;

FIG. 5 is a side view of the liquid-cooling heat sink in FIG. 1;

FIG. 6 is an operational top view of the liquid-cooling heat sink in FIG. 1;

FIG. 7 is an operational side view of the liquid-cooling heat sink in FIG. 1.

### DETAILED DESCRIPTION OF INVENTION

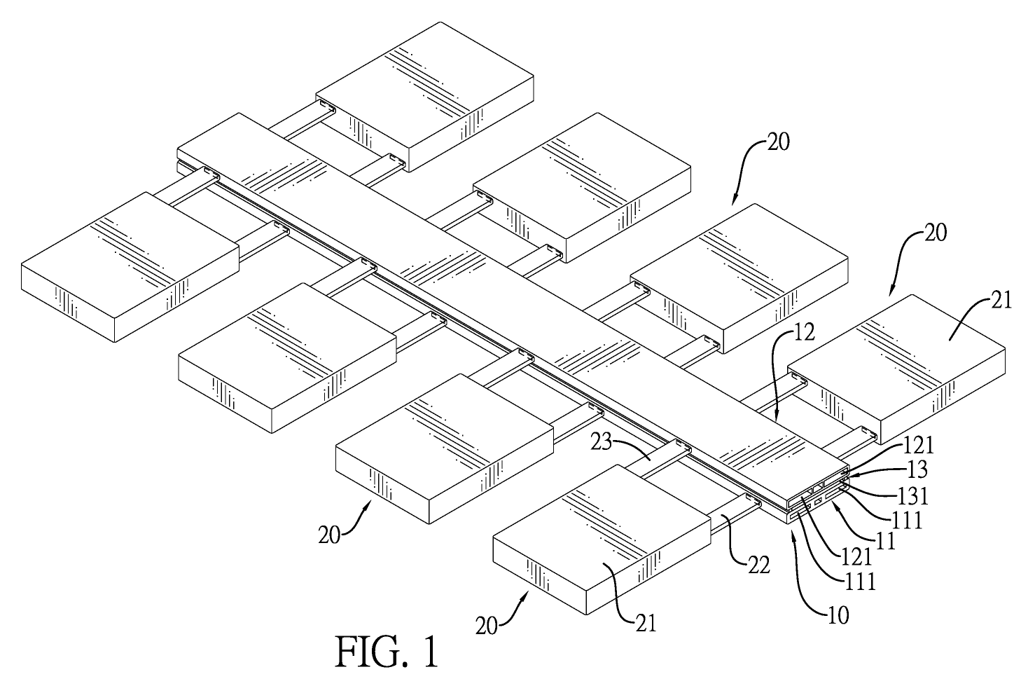

With reference to FIG. 1, a liquid-cooling heat sink in accordance with the present invention comprises a heat-conductive tube 10 and two sets of multiple heat-conductive units 20.

With reference to FIGS. 1 to 3, the heat-conductive tube 10 has a first end, a second end, two opposite sides, a first tube 11, a second tube 12, and an isolation member 13.

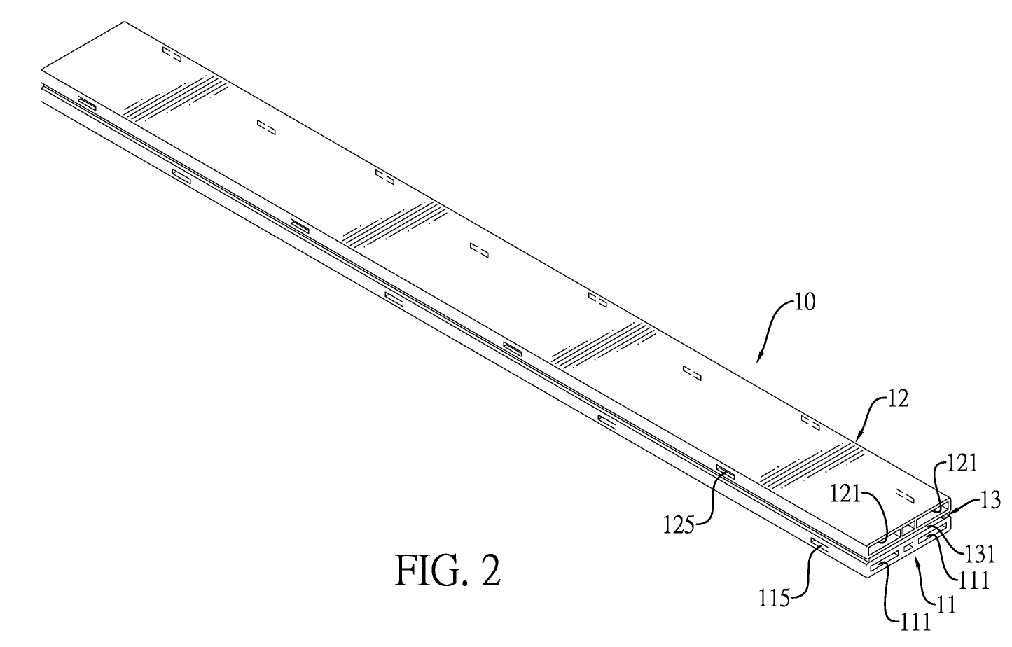

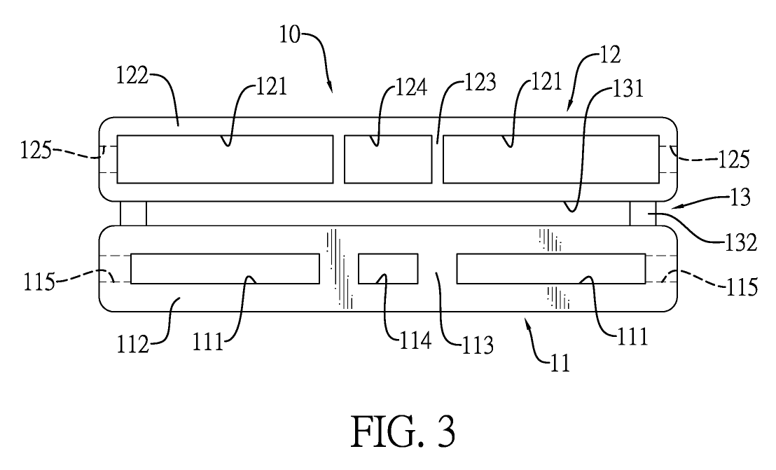

With reference to FIGS. 2 and 3, the first tube 11 has at least one first fluid channel 111 and a first wall 112. The at least one first fluid channel 111 is defined longitudinally in the first tube 11. The first wall 112 surrounds the at least one first fluid channel 111.

With reference to FIGS. 2 and 3, in a preferred embodiment, the first tube 11 is elongated. The first tube 11 has two first fluid channels 111. The first tube 11 further has a first partition 113, a first compartment channel 114, and multiple first mounting holes 115. The first partition 113 is formed between the two first fluid channels 111. The first compartment channel 114 is formed in the first partition 113. The first compartment channel 114 and the first fluid channels 111 extend along an axial direction of the first tube 11. The first mounting holes 115 are defined in the first wall 112 at spaced intervals and communicate with the two first fluid channels 111 and an outer surface of the first tube 11.

With reference to FIGS. 2 and 3, the second tube 12 is arranged adjacent to the first tube 11. The second tube 12 has at least one second fluid channel 121 and a second wall 122. The at least one second fluid channel 121 is defined longitudinally in the second tube 12. The second wall 122 surrounds the at least one second fluid channel 121.

In the preferred embodiment, the second tube 12 is elongated and is located above the first tube 11. The second tube 12 has two second fluid channels 121. The second tube 12 further has a second partition 123, a second compartment channel 124, and multiple second mounting holes 125. The second partition 123 is formed between the two second fluid channels 121. The second compartment channel 124 is formed in the second partition 123. The second compartment channel 124 and the second fluid channels 121 extend along an axial direction of the second tube 12. The second mounting holes 125 are defined in the second wall 122 at spaced intervals and communicate with the two second fluid channels 121 and an outer surface of the second tube 12.

With reference to FIGS. 2 and 3, the isolation member 13 is formed between and connects to the first tube 11 and the second tube 12. The isolation member 13 has one isolation channel 131 and multiple connecting walls 132. The isolation channel 131 is defined between the first tube 11 and the second tube 12. The connecting walls 132 surround the isolation channel 131. The connecting walls 132 connect to the first wall 112 of the first tube 11 and the second wall 122 of the second tube 12.

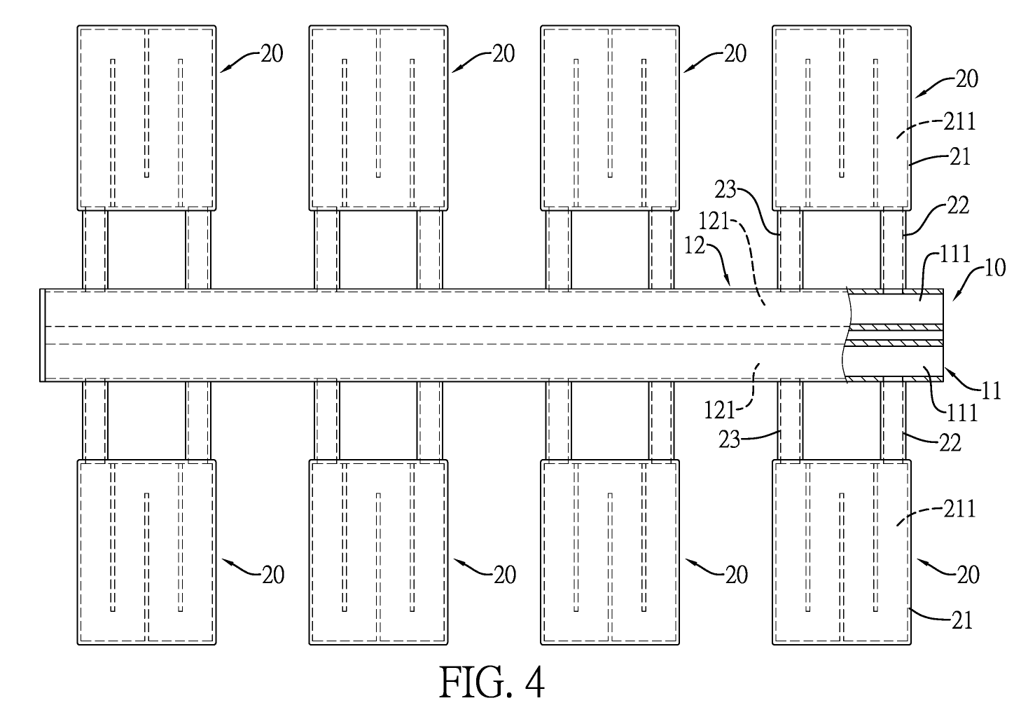

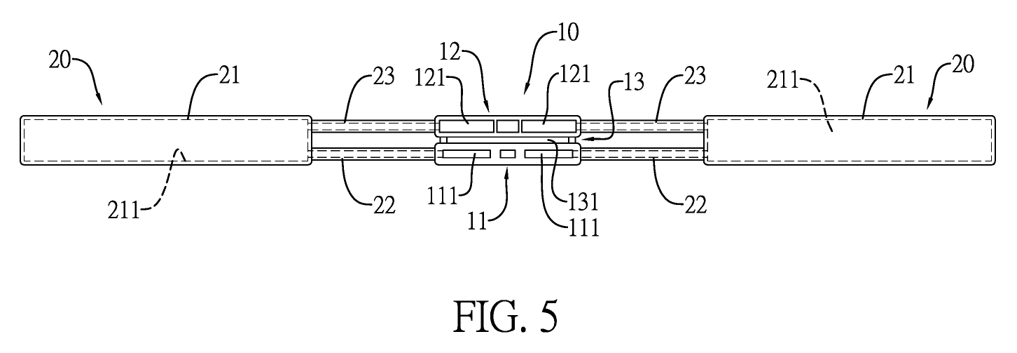

With reference to FIGS. 1, 4 and 5, the first fluid channel 111 of the first tube 11 has two ends. The second fluid channel 121 of the second tube 12 has two ends. In one preferred embodiment, the two ends of the first fluid channel 111 are two open ends, and the two ends of the second fluid channel 121 are two open ends. In another preferred embodiment, the two ends of the first fluid channel 111 are an open end and a closed end, and the two ends of the second fluid channel 121 are an open end and a closed end. The closed end of the first fluid channel 111 and the closed end of the second fluid channel 121 are both at the first end of the heat-conductive tube 10 or are respectively at the first end and the second end of the heat-conductive tube 10. The open end of the first fluid channel 111 of the first tube 11 is the inlet of the cooling liquid. The open end of the second fluid channel 121 of the second tube 12 is the outlet of the hotter cooling liquid.

With reference to FIGS. 1, 4 and 5, in the preferred embodiment, the sets of the heat-conductive units 20 are located respectively on the two opposite sides of the heat-conductive tube 10 and connect to the heat-conductive tube 10 in parallel. Each heat-conductive unit 20 has a heat-conductive body 21, a first delivery tube 22, and a second delivery tube 23. Each heat-conductive body 21 has a fluid channel 211. Each fluid channel 211 has an entrance end and an exit end. Each fluid channel 211 is continuously curved. Each first delivery tube 22 has two ends. One end of the first delivery tube 22 connects to the entrance end of the fluid channel 211. The other end of the first delivery tube 22 connects to one of the first mounting holes 115. Each first delivery tube 22 communicates with the at least one first fluid channel 111 and the heat-conductive units 20. Each second delivery tube 23 has two ends. One end of the second delivery tube 23 connects to the exit end of the fluid channel 211. The other end of the second delivery tube 23 connects to one of the second mounting holes 125. Each second delivery tube 23 communicates with the second fluid channel 121 and the heat-conductive units 20.

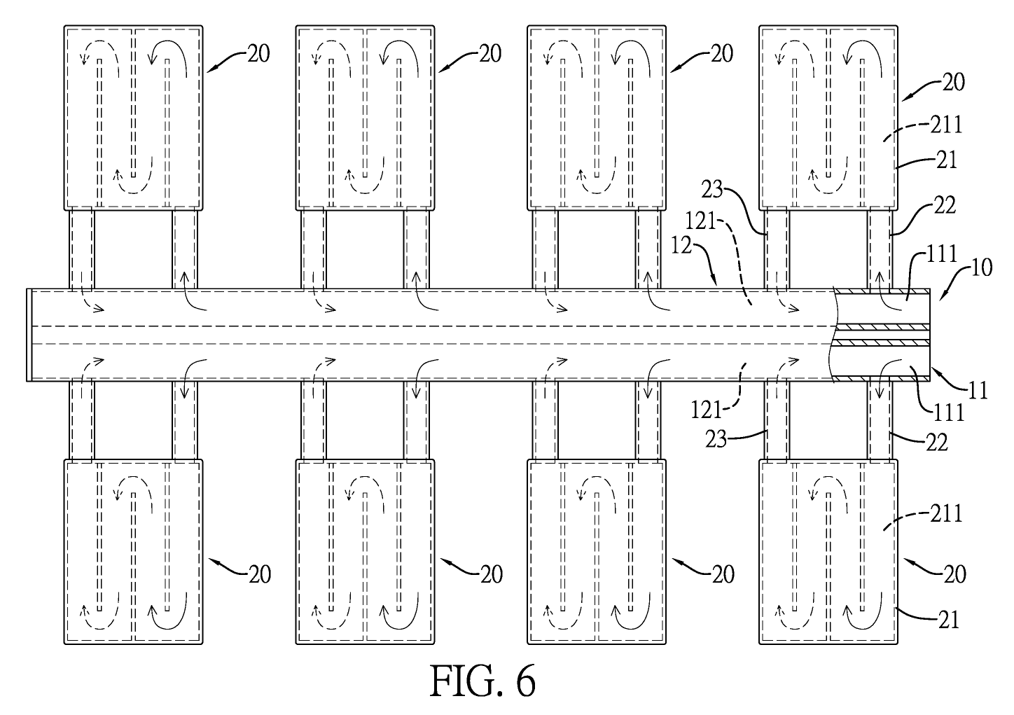

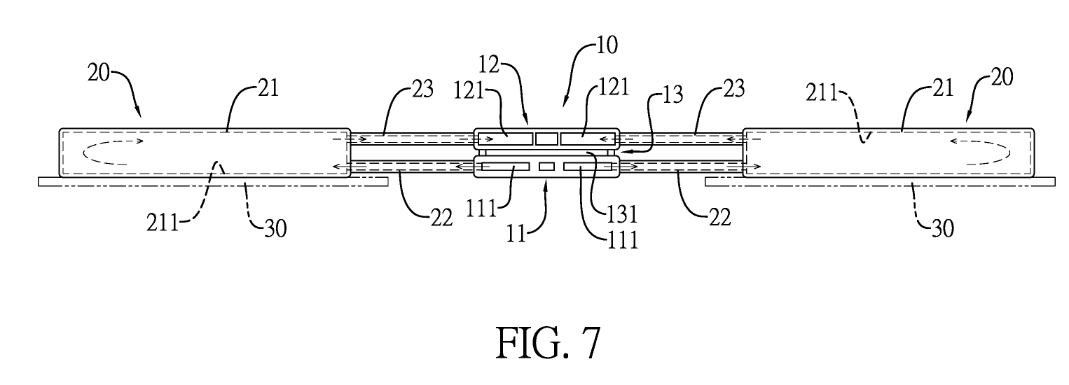

With reference to the FIGS. 6 and 7, to operate the liquid-cooling heat sink, each of the heat-conductive bodies 21 of the heat-conductive units 20 contacts a heat source 30. The heat generated by the heat sources 30 is transferred to the heat-conductive bodies 21. The cooling liquid, such as water or refrigerant, is supplied from a cooling liquid source. The cooling liquid enters the first tube 11 from the open end of the first fluid channel 111 and is distributed to the heat-conductive bodies 21 through the first delivery tubes 22. The cooling liquid absorbs heat when flowing through the fluid channels 211 of the heat-conductive bodies 21. Then, the cooling liquid becomes a hotter cooling liquid. The hotter cooling liquid flows through the second delivery tubes 23 and converges in the second fluid channel 121. The hotter cooling liquid flows to the open end of the second fluid channel 121 and refluxes to the cooling liquid source. After the heat dissipating process for a device around the cooling liquid source, the hotter cooling liquid is cooled and flows to the open end of the first fluid channel 111 again. By circulation of the cooling liquid, the liquid-cooling heat sink is able to continuously dissipate heat from the heat source 30.

Furthermore, the isolation channel 131 formed in the isolation member 13 accommodates air and serves as an air layer for thermal insulation. The air layer obstructs heat exchange between the first tube 11 and the second tube 12 during the flowing process of the cooling liquid in the heat-conductive tube 10. The air layer makes the first tube 11 and the second tube 12 independent from each other. Therefore, the cooling liquid flowing in the first tube 11 will not be influenced by the hotter cooling liquid flowing in the second tube 12 above and may maintain the capability of heat dissipation.

What is claimed is:

1. A liquid-cooling heat sink comprising:
a heat-conductive tube having
two opposite sides;
a first tube having
at least one first fluid channel defined longitudinally in the first tube;
a first wall surrounding the at least one first fluid channel;
a second tube formed on the first tube;
a second tube having
at least one second fluid channel defined longitudinally in the second tube; and
a second wall surrounding the at least one second fluid channel; and
an isolation member formed between and connecting to the first tube and the second tube and having
at least one isolation channel defined between the first tube and the second tube; and
multiple connecting walls surrounding the at least one isolation channel and connecting the first wall of the first tube and the second wall of the second tube; and
multiple heat-conductive units located on the two opposite sides of the heat-conductive tube, and each heat-conductive unit having
a heat-conductive body having a fluid channel; each fluid channel having an entrance end and an exit end;
a first delivery tube having two ends, one end of the first delivery tube connecting to the entrance end of the fluid channel, and the other end of the first delivery tube connecting to the at least one first fluid channel of the first tube; and
a second delivery tube having two ends, one end of the second delivery tube connecting to the exit end of the fluid channel, and the other end of the second delivery tube connecting to the at least one second fluid channel of the second tube.

2. The liquid-cooling heat sink as claimed in claim 1, wherein
the at least one first fluid channel is implemented as multiple first fluid channels;
a first partition is formed between each two adjacent first fluid channels; and
at least one first compartment channel is formed in each first partition.

3. The liquid-cooling heat sink as claimed in claim 1, wherein
the at least one second fluid channel is implemented as multiple second fluid channels;
a second partition is formed between each two adjacent second fluid channels; and
at least one second compartment channel is formed in each second partition.

4. The liquid-cooling heat sink as claimed in claim 1, wherein
the at least one first fluid channel is implemented as multiple first fluid channels;
a first partition is formed between each two adjacent first fluid channels;
at least one first compartment channel is formed in each first partition;
the at least one second fluid channel is implemented as multiple second fluid channels;
a second partition is formed between each two adjacent second fluid channels; and
at least one second compartment channel is formed in each second partition.

5. The liquid-cooling heat sink as claimed in claim 4, wherein
the first tube is elongated;
the first tube has two first fluid channels, one first partition, and one first compartment channel;
the first compartment channel and the first fluid channels extend along an axial direction of the first tube; the second tube is elongated;
the second tube is located above the first tube;
the second tube has two second fluid channels, one second partition, and one second compartment channel; and
the second compartment channel and the two second fluid channels extend along an axial direction of the second tube.

6. The liquid-cooling heat sink as claimed in claim 5, wherein
the fluid channel is continuously curved.

7. The liquid-cooling heat sink as claimed in claim 5, wherein
the heat-conductive units are arranged into two sets located respectively on the two opposite sides of the heat-conductive tube; and
the fluid channel of the heat-conductive body is continuously curved.
